(19) United States
(12) Patent Application Publication
(10) Pub. No.: US 2007/0202446 A1
(43) Pub. Date: Aug. 30, 2007

(54) Semiconductor device fabrication method having step of removing photo-resist film or the like, and photo-resist film removal device

(75) Inventors: Osamu Takahashi, Kawasaki (JP); Tetsuo Yaegashi, Kawasaki (JP)

Correspondence Address: WESTERMAN, HATTORI, DANIELS & ADRIAN, LLP, 1250 CONNECTICUT AVENUE, NW, SUITE 700, WASHINGTON, DC, 20036, US

(73) Assignee: FUJITSU LIMITED, Kawasaki (JP)

(21) Appl. No.: 11/445,325

(22) Filed: Jun. 2, 2006

(30) Foreign Application Priority Data
Feb. 28, 2006 (JP) 2006-052576

(51) Int. Cl. G03F 7/26

(52) U.S. Cl. 430/329; 430/311

(57) ABSTRACT

In the step of removing the photo-resist film formed on a substrate, dry ice particles, with a predetermined particle size, are blasted onto the photo-resist film at a predetermined pressure in a state of heating the substrate at room temperature or higher, such as 30 to 200° C., preferably at about 100° C.

### CROSS-REFERENCE TO RELATED APPLICATIONS

This application is based upon and claims the benefit of priority from the prior Japanese Patent Application No. 2006-52576, filed on Feb. 28, 2006, the entire contents of which are incorporated herein by reference.

### BACKGROUND OF THE INVENTION

1. Field of the Invention

The present invention relates to a semiconductor device fabrication method having a step of removing photo-resist film or the like and a photo-resist film removal device, and more particularly to an environmental friendly method and device which do not cause plasma damage to wafers.

2. Description of the Related Art

In a semiconductor fabrication process, a photo-sensitive photo-resist film is coated, exposed and developed, then using this as a mask, various processings, such as etching processing and ion implantation processing, are performed, and finally the photo-resist film is removed, and this series of processing steps are repeated. Therefore the photo-resist film removal steps are repeated many times. In a conventional general photo-resist film removal step, oxygen radicals or fluorine radicals are generated by exciting oxygen gas or fluorine gas in a plasma atmosphere, and supplied to a reduced pressure chamber where a wafer substrate, on which a photo-resist film is formed, is stored so that the oxygen or fluorine radicals and hydro-carbon, which is the main component of photo-resist film, are reacted and incinerated. The wafer substrate in the reduced-pressure chamber is placed on a heater stage and heated, and because oxygen or fluorine radicals are supplied in this heating status, the reaction speed is increased, and the throughput of the photo-resist removal step is improved.

Another method proposed, other than this plasma processing, is that in the step of forming a metal film on a patterned photo-resist film, removing the photo-resist film and lifting off the metal film so as to form a patterned metal film on the substrate, the metal film is removed along with the photo-resist film by blasting dry ice particles. An example of this is disclosed in Japanese Patent Application Laid-Open No. 2000-58546 (published on Feb. 25, 2000).

As a method of removing the photo-resist film after ion implantation, a moisturizing step for moisturizing the photo-resist film is executed, then freezing treatment is performed, then blasting sublimating or melting type solid particles (e.g. dry ice particles, ice particles) so as to clean and remove the photo-resist film from the wafer substrate has been proposed. An example of this is Japanese Patent Application Laid-Open No. 2000-58494 (published on Feb. 25, 2000).

As a cleaning method of electronic equipment, although this is not a photo-resist removal method, it has been proposed to clean components, of which the specific gravity is lower than the liquid form cleaning medium, by blasting dry ice particles. An example of this is Japanese Patent Application Laid-Open No. 2004-8995 (published on Jan. 15, 2004).

### SUMMARY OF THE INVENTION

In the case of a conventional method of removing the photo-resist film by incinerating it by plasma processing, plasma damage occurs, such as charges are stored on the wafer surface causing an electrostatic breakdown of the gate insulation film, which is not desirable. The use of fluorine gas causes environmental problems, which is not desirable, and the use of oxygen gas requires the installation of equipment necessary for using oxygen gas as a reactive gas, which is also not desirable.

A method of blasting dry ice particles has been proposed as a method of removing the photo-resist film, but the surface of photo-resist film after ion implantation is hardened, and cannot be sufficiently removed merely by blasting dry ice particles. Therefore in the above mentioned Japanese Patent Application Laid-Open No. 2000-58494, for example, dry ice particles are blasted after pretreatment, such as a moisturizing treatment and freezing treatment, but this inevitably drops the throughput.

With the foregoing in view, it is an object of the present invention to provide a semiconductor device fabrication method having a photo-resist film removal step and a photo-resist film removal device for removing photo-resist film without requiring the supply of reactive gas and without requiring the generation of plasma.

To achieve this object, a first aspect of the present invention is that in the step of removing the photo-resist film formed on a substrate, dry ice particles, with a predetermined particle size, are blasted onto the photo-resist film at a predetermined pressure in a state of heating the substrate at room temperature or higher, such as 30 to 200° C., preferably at about 100° C.

For example, the surface of the photo-resist film after the ion implantation step is hardened, so in order to remove this, it is necessary to blast dry ice particles with a relatively large particle size at a relatively high pressure. In this case, the substrate is heated, so the dry ice particles blasted onto the substrate at a high substrate temperature evaporate and do not damage the substrate, but the photo-resist film, of which temperature is not as high as the substrate, can be effectively removed by physical interaction due to the blasting pressure of the dry ice particles.

To achieve the above object, the second aspect of the present invention provides a step of removing a photo-resist film formed on a substrate, wherein a surface layer of the photo-resist film is removed by blasting dry ice particles with a first particle size at a first pressure, and an internal layer of the photo-resist film is removed by blasting dry ice particles with a second particle size, which is smaller than the first particle size, at a second pressure which is lower than the first pressure. The surface layer in a hardened status is removed by a stronger physical force, but an unhardened internal layer is removed by a not so strong physical force, so as to minimize the damage on the substrate.

To achieve the above objects, a third aspect of the present invention provides a semiconductor device fabrication method having a step of forming a photo-resist film on a substrate, a step of patterning the photo-resist film by exposure and development, a step of processing the surface of the substrate using the patterned photo-resist film as a mask, and removing the photo-resist film by blasting dry ice particles with a predetermined particle size onto the photo-resist film at a predetermined injection pressure in a state of heating the substrate.

To achieve the above objects, a fourth aspect of the present invention provides a semiconductor device fabrication method, having a step of forming a photo-resist film on a substrate, a step of patterning the photo-resist film by exposure and development, a step of implanting ions into the substrate using the patterned photo-resist film as a mask, and a step of removing a surface layer of the photo-resist film by blasting dry ice particles with a first particle size to the photo-resist film at a first injection pressure, and removing an internal layer of the photo-resist film by blasting dry ice particles with a second particle size, which is smaller than the first particle size, onto the photo-resist film at a second injection pressure, which is lower than the first injection pressure in a state of heating the substrate.

To achieve the above object, a fifth aspect of the present invention provides a semiconductor fabrication method, having a step of forming a removal film of which the surface layer is harder than the internal layer on a substrate, and a step of removing the surface layer of the removal film by blasting dry ice particles with a first particle size to the removal film at a first injection pressure, and removing the internal layer of the removal film by blasting dry ice particles with a second particle size, which is smaller than the first particle size, onto the removal film at a second injection pressure, which is lower than the first injection pressure.

To achieve the above object, a sixth aspect of the present invention provides a semiconductor device fabrication method, having a step of forming a photo-resist film on a substrate, a step of patterning the photo-resist film by exposure and development, a step of implanting ions into the substrate using the patterned photo-resist film as a mask, and a step of removing the surface layer of the photo-resist film by blasting dry ice particles with a first particle size onto the photo-resist film at a first injection pressure, and removing an internal layer of the photo-resist film by blasting dry ice particles with a second particle size, which is smaller than the first particle size, onto the photo-resist film at a second injection pressure, which is lower than the first injection pressure, wherein the first and second particle sizes are in a 10 to 100 μm range, and the first and second injection pressures are in a 0.2 to 1.0 Mpa range.

To achieve the above object, a seventh aspect of the present invention is a photo-resist film removal device for removing a photo-resist film formed on a substrate, having a heater stage where a substrate on which the photo-resist film is formed is placed and heated, a dry ice generation unit for generating dry ice particles with a predetermined particle size, and an injection nozzle for injecting dry ice particles generated by the dry ice generation unit to the photo-resist film on the substrate surface at a predetermined injection pressure, wherein the photo-resist film is removed by blasting dry ice particles with a predetermined particle size through the injection nozzle onto the photo-resist film at a predetermined injection pressure in a state of heating the substrate.

According to the above aspects of the present invention, photo-resist film can be removed without supplying reactive gas and without the generation of plasma. Particularly the present invention is effective to remove the photo-resist film exposed in the ion implantation step.

### BRIEF DESCRIPTION OF THE DRAWINGS

FIG. 1 are diagrams depicting the problems of the ashing removal step of a photo-resist film;

FIG. 2 are diagrams depicting the photo-resist film removal method according to the present embodiment;

FIG. 3 is a diagram depicting the configuration of the photo-resist film removal device according to the present invention;

FIG. 4 is a diagram depicting the configuration of the photo-resist film removal device according to the present invention; and

FIG. 5 is a table showing the conditions of removal by blasting dry ice particles according to the present example.

### DESCRIPTION OF THE PREFERRED EMBODIMENTS

Embodiments of the present invention will now be described. The technical scope of the present invention, however, will not be limited to these embodiments, but extend to the contents stated in the Claims and equivalents thereof.

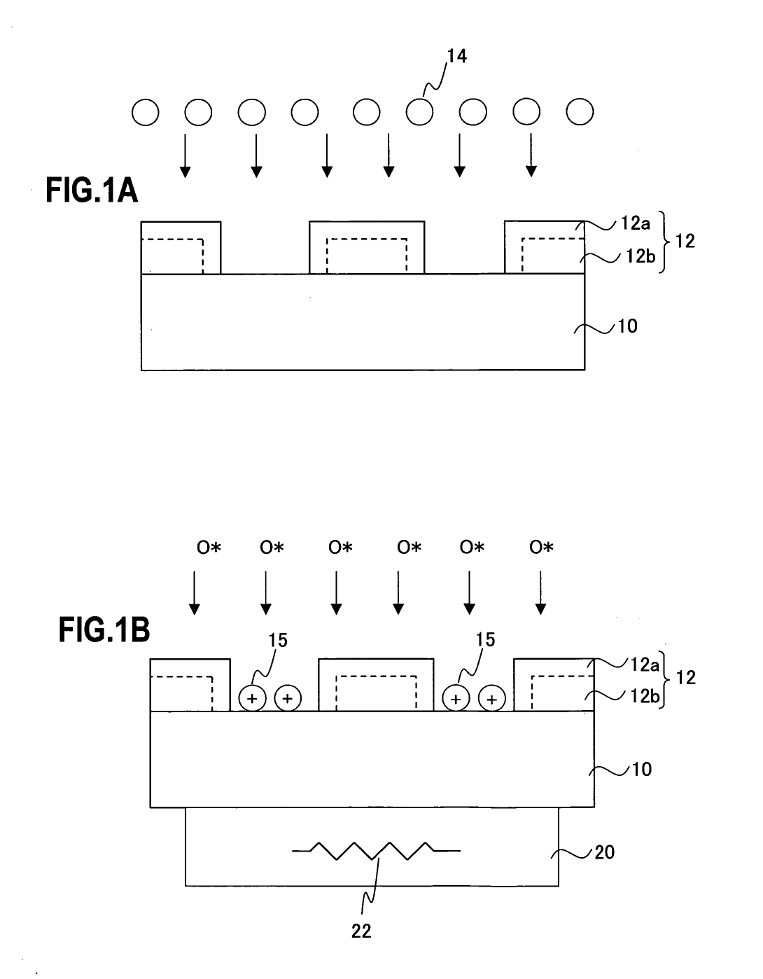

FIG. 1 are diagrams depicting the problems of the ashing removal step of the photo-resist film. As FIG. 1A shows, the photo-resist film 12 is formed on the silicon semiconductor substrate 10, and patterned by exposure and development, and ions are implanted using the patterned photo-resist film 12 as a mask. The implantation ions 14 are also implanted into a part of the substrate 10 where the photo-resist film 12 is not formed, and are also implanted into the surface of the photo-resist film 12. Photo-resist film 12 is normally a high polymer organic material film, and when ions are implanted, the surface thereof is baked and hardened by ion energy. As a result, the photo-resist film 12 after the ion implantation step is comprised of a hardened surface layer 12a and an internal layer 12b, which is not hardened and softer than the surface layer 12a.

To remove this photo-resist film 12 by ashing, plasma-excited oxygen radicals 0* are supplied to the surface of the substrate 10 while heating the substrate 10 to about 250° C., for example, as FIG. 1B shows, then the oxygen radicals and photo-resist film 12 are oxidized, and the photo-resist film 12 is incinerated. Heating improves the reaction speed.

However the photo-resist film 12 cannot be removed sufficiently by plasma ashing since the surface layer 12a thereof is hardened, and if the photo-resist film 12 is placed in a heating status for a long time, the thermal expansion of the internal layer 12b, which is not as hard as much as the surface layer 12a, causes an explosion of the photo-resist film 12 and the affected photo-resist material attaches to the surface of the substrate. The affected material attached once cannot be completely removed by the plasma ashing step.

Also the photo-resist film is exposed in an atmosphere of oxygen radicals excited by plasma for a long time, so charges 15 are stored on the surface of the substrate, and the gate film on the surface of the substrate is also damaged by electrostatic breakdown.

In the present embodiment, the photo-resist film which was used as a mask in the ion implantation step is physically removed by blasting sublimating particles, such as dry ice particles, without using plasma and without using reactive gas.

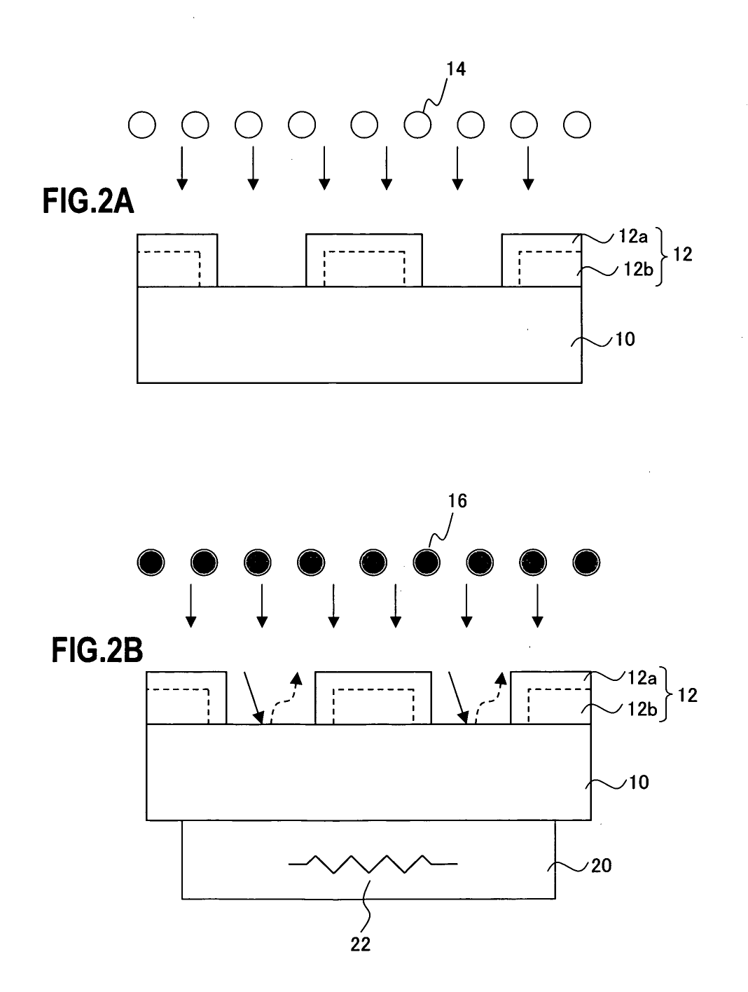

FIG. 2 are diagrams depicting the photo-resist film removal method according to the present embodiment. FIG. 2A is the same as FIG. 1A, wherein the photo-resist film 12 is formed on the silicon semiconductor substrate 10 and patterned by exposure and development, and ions are implanted using the patterned photo-resist film 12 as a mask. The implantation ions 14 are also implanted into the surface of the photo-resist film 12, and the surface is baked and hardened. As a result, the photo-resist film 12 after the ion implantation step is comprised of a hardened surface layer 12a and the internal layer 12b, which is not hardened and softer than the surface layer 12a.

As FIG. 2B shows, according to the present embodiment, the substrate 10 is placed on the heater stage 20, and the photo-resist film 12 on the surface of the substrate is physically removed by blasting the dry ice particles 16 with a predetermined particle size at a predetermined injection pressure, while heating the substrate 10 by the heater 22. The dry ice particles are solid particles of carbon dioxide, and an appropriate particle size thereof is about 10-100 μm. An appropriate injection pressure is about 0.2-1.0 Mpa. And an appropriate heating temperature of the substrate is 30-200° C., preferably about 100° C. This heating temperature is a low temperature compared with the heating temperature in the ashing step (about 250° C.) in FIG. 1. By suppressing the heating temperature, the explosion phenomena of the photo-resist film, which occurs in the ashing step, is suppressed.

If the film thickness of the photo-resist film 12 is about 700-2500 nm, the blasting time of dry ice particles is about 10-60 nsec., for example, so the photo-resist film can be removed in a relatively short time.

If dry ice particles 16 are blasted while heating the substrate 10, the silicon substrate 10 which has high thermal conductivity is at high temperature status, so the blasted dry ice particles 16 are sublimated and evaporated on the surface of the substrate 10, and exhausted as carbon dioxide gas. Therefore the surface of the substrate is not damaged very much. The photo-resist film 12, which has low thermal conductivity, on the other hand, does not reach such a high temperature, so the photo-resist film 12 is removed by the physical impact of blasted dry ice particles 16.

In this way, the substrate heating temperature, which purpose is not to promote a reaction with the reactive gas, like the case of the ashing step, can be relatively low, and the explosion phenomena of the internal layer 12b of the photo-resist film 12 by thermal expansion can be suppressed. In other words, the substrate heating temperature is preferably kept at a temperature low enough not to cause an explosion of the photo-resist film.

According to the blast method using dry ice particles, it is unnecessary to create the plasma status, and is also unnecessary to use reactive gas. Also by heating the substrate, damage of the surface of the substrate can be suppressed. Therefore the photo-resist film can be removed without damaging the substrate very much, and without using reactive gas. Particularly the blast method using dry ice particles according to the present embodiment is effective for the photo-resist film used as a mask for ion implantation, since the surface layer thereof is hardened.

In the case of the photo-resist film 12 after undergoing the ion implantation step, the surface layer 12a is a hardened layer and the internal layer 12b is an unhardened layer. So in the present embodiment, when the surface layer 12a is removed, the dry ice particles with a relatively large first particle size is blasted onto the photo-resist film at a relatively high first injection pressure, and when the internal layer 12b is removed, dry ice particles with a small second particle size, which is smaller than the first particle size, is blasted onto the photo-resist film at a low second injection pressure, which is lower than the first injection pressure. In this way, the hard layer is removed by blasting dry ice particles with a relatively large particle size at a higher injection pressure. The internal layer 12b which is not hard, however, can be removed by blasting dry ice particles with a smaller particle size at a lower injection pressure, therefore unnecessary damage to the substrate can be avoided.

According to the present embodiment, the first and second particle sizes are in a 10-100 μm range, and the first and second injection pressures are in a 0.2-1.0 Mpa range. The first and second particles sizes and the first and second injection pressures are selected according to the hardness of the photo-resist film to be removed.

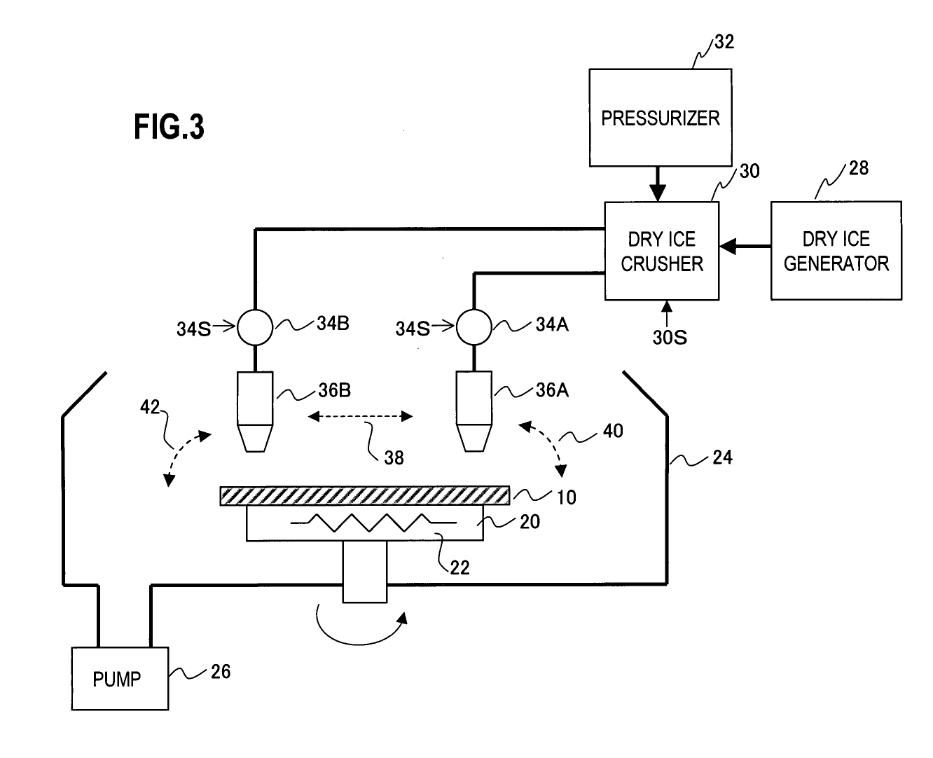

FIG. 3 is a diagram depicting the configuration of the photo-resist removal device according to the present embodiment. This removal device comprises a dry ice generator 28, dry ice crusher 30 which crushes the block of generated dry ice to be an appropriate particle size, and a pressurizer 32 for pressurizing the crushed dry ice particles by such an inactive gas as nitrogen. The pressurized dry ice particles are blasted onto the surface of the substrate 10 from the dry ice crusher 30 using the injection nozzle 36 via the pressure control section 34. The substrate 10 is mounted on the heater stage 20 having a heater 22, and is rotated as shown by the solid line arrow mark when necessary.

The heater stage 20 is stored in the atmospheric chamber 24, and a pressure reducing pump 26 is connected to the atmospheric chamber 24, and air in the atmosphere of the heater stage 20 is exhausted. By this, the photo-resist film physically removed by blasting the dry ice particles, and carbon dioxide evaporated by the heated substrate, are exhausted.

To the dry ice crusher 30, a particle size control signal 30S for controlling the crushed particle size is supplied, so that the dry ice can be crushed to be a desired particle size. To the pressure control section 34, the pressure control signal 34S is supplied so that the injection pressure can be controlled to be a desired pressure.

In the device in FIG. 3, there are two injection nozzles, 36A and 36B, for blasting the dry ice particles, which can blast dry ice particles with the same particle size at the same injection pressure respectively, or with different particle sizes and at different injection pressures respectively. The injection nozzles 36A and 36B can move in the direction indicated by the broken line 38, so that the dry ice particles can be blasted onto the entire front face of the substrate 10. The injection nozzles 36A and 36B can also move in the directions of the broken lines 40 and 42, so that the dry ice particles can be blasted onto the peripheral area of the substrate 10 and the edges of the peripheral area, as well as onto the back face of the peripheral area.

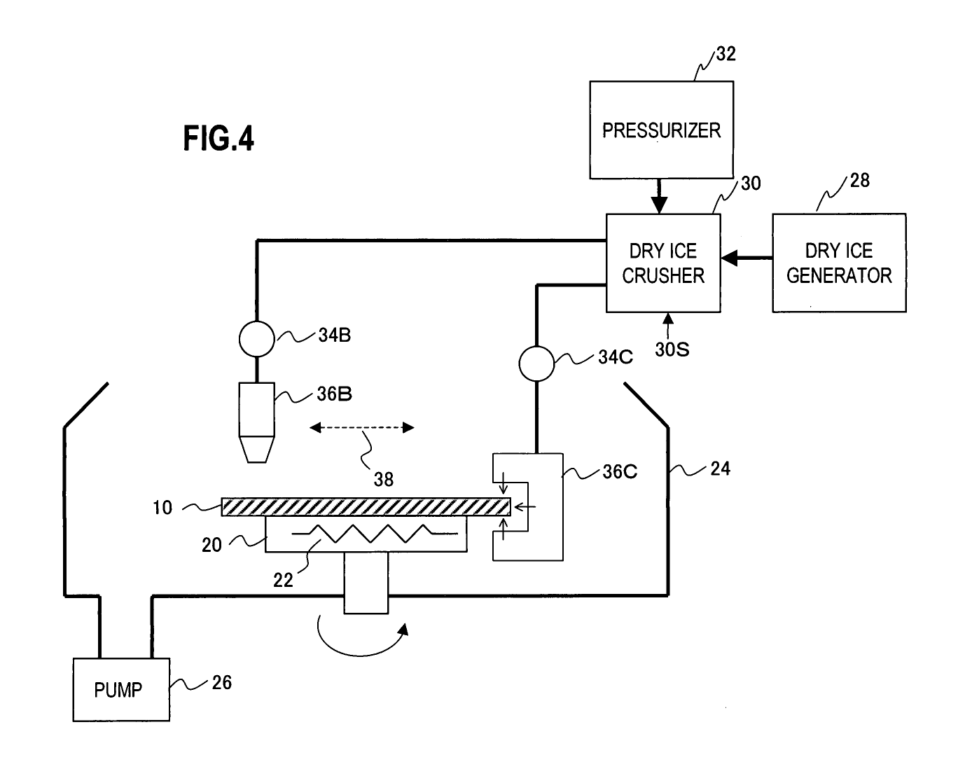

FIG. 4 is a diagram depicting the configuration of another photo-resist film removal device according to the present embodiment. This device comprises the pressure control section 34C and the U-shaped injection nozzle 36C, instead of the pressure control section 34A and the injection nozzle 36A in FIG. 3. The rest of the configuration is the same as FIG. 3.

The U-shaped injection nozzle 36C has nozzles such that dry ice particles can be injected in three directions, as the arrow marks in FIG. 4 show. Therefore by rotating the substrate 10, the dry ice particles can be blasted onto the peripheral area of the substrate 10, the edges of the peripheral area, as well as onto the back face of the peripheral area. And by moving another nozzle 36B in the direction of the broken line arrow mark 38 while rotating the substrate 10, dry ice particles can be blasted onto the entire front surface of the substrate 10.

### EXAMPLE

As described in FIG. 2, the photo-resist made by Sumitomo Chemical Co. Ltd. (name: PFI32A6) is coated to about 710 nm on the silicon semiconductor substrate, and patterned by exposure and development. Then using the patterned photo-resist film as a mask, P, as the impurity ions for a 2.0 E15 dosage, is implanted at a 15 keV implantation energy. After ion implantation, the photo-resist film is removed by the removal device of the present embodiment.

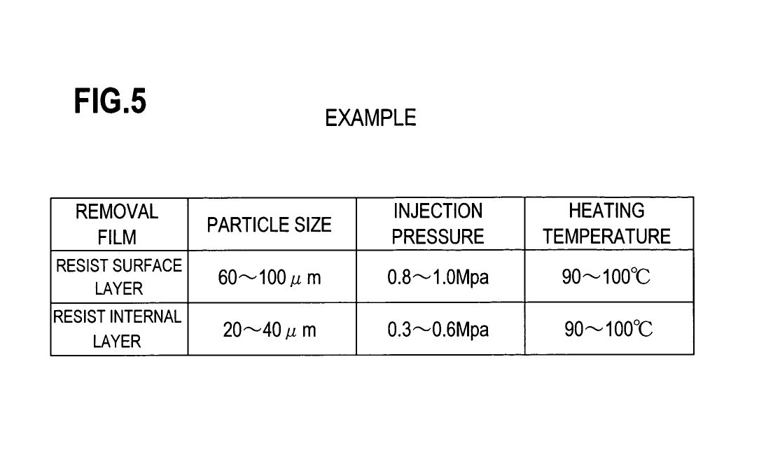

FIG. 5 is a table showing the removal conditions by blasting dry ice particles according to the present embodiment. As this table shows, the hardened surface layer of the photo-resist film is removed by blasting dry ice particles with a 60-100 μm particle size at a 0.8-1.0 Mpa injection pressure at a 90°-100° C. heating temperature for about 30 sec. The inner layer of the photo-resist film is removed by blasting dry ice particles with a 20-40 μm particle size at a 0.3-0.6 Mpa injection pressure at a 90°-100° C. heating temperature for about 30 sec.

According to the present example, the photo-resist film after ion implantation can be removed. And damage on the substrate is more suppressed compared with the conventional ashing method. In the above embodiment and example, the removed method by dry ice particles was described using photo-resist film as an example. The present invention, however, is also effective for physically removing thin films formed on the substrate, other than the photo-resist film. In this case, an optimum particle size and injection pressure of the dry ice particles are selected according to the hardness of the removal film. An example of the removal film is SIO film.

What is claimed is:

1. A semiconductor device fabrication method, comprising the steps of:
forming a photo-resist film on a substrate;
patterning said photo-resist film by exposure and development;
processing a surface of said substrate using said patterned photo-resist film as a mask; and
removing said photo-resist film by blasting dry ice particles with a predetermined particle size onto the photo-resist film at a predetermined injection pressure in a state of heating said substrate.

2. The semiconductor device fabrication method according to claim 1, wherein in said step of processing the surface of said substrate, ions are implanted into said substrate with said photo-resist film being as a mask.

3. The semiconductor device fabrication method according to claim 1, wherein in said step of removing said photo-resist film, the heating temperature of said substrate is 30 to 200° C., said predetermined particle size is 10 to 100 μm, and said predetermined injection pressure is 0.2 to 1.0 Mpa.

4. The semiconductor device fabrication method according to claim 2, wherein in said step of removing said photo-resist film, the heating temperature of said substrate is 30 to 200° C., said predetermined particle size is 10 to 100 μm, and said predetermined injection pressure is 0.2 to 1.0 Mpa.

5. A semiconductor device fabrication method, comprising the steps of:
forming a photo-resist film on a substrate;
patterning said photo-resist film by exposure and development;
implanting ions into said substrate using said patterned photo-resist film as a mask; and
removing a surface layer of said photo-resist film by blasting dry ice particles with a first particle size onto said photo-resist film at a first injection pressure, and removing an internal layer of said photo-resist film by blasting dry ice particles with a second particle size, which is smaller than said first particle size, onto said photo-resist film at a second injection pressure, which is lower than the first injection pressure, in a state of heating said substrate.

6. The semiconductor device fabrication method according to claim 5, wherein in said step of removing said photo-resist film, the heating temperature of said substrate is 30 to 200° C., said first and second particle sizes are in a 10 to 100 μm range, and said first and second injection pressures are in a 0.2 to 1.0 Mpa range.

7. The semiconductor device fabrication method according to claim 5, wherein in said step of removing said photo-resist film, the heating temperature of said substrate is 30 to 200° C., said first particle size is 60 to 100 μm, said second particle size is 20 to 40 μm, said first injection pressure is 0.8 to 1.0 Mpa, and said second injection pressure is 0.3 to 0.6 Mpa.

8. A semiconductor device fabrication method, comprising the steps of:
forming a removal film of which surface layer is harder than an internal layer on a substrate; and
removing the surface layer of said removal film by blasting dry ice particles with a first particle size onto said removal film at a first injection pressure, and removing the internal layer of said removal film by blasting dry ice particles with a second particle size, which is smaller than said first particle size, onto said removal film, at a second injection pressure, which is lower than the first injection pressure in a state of heating said substrate.

9. A semiconductor device fabrication method, comprising the steps of:
forming a photo-resist film on a substrate;
patterning said photo-resist film by exposure and development;
implanting ions into said substrate using said patterned photo-resist film as a mask; and
removing a surface layer of said photo-resist film by blasting dry ice particles with a first particle size onto said photo resist film at a first injection pressure, and removing an internal layer of said photo-resist film by blasting dry ice particles with a second particle size, which is smaller than said first particle size, onto said photo-resist film at a second injection pressure, which is lower than the first injection pressure, wherein
said first and second particle sizes are in a 10 to 100 μm range, and said first and second injection pressures are in a 0.2 to 1.0 Mpa range.

10. A photo-resist film removal device for removing a photo-resist film formed on a substrate, comprising:
a heater stage where a substrate on which said photo-resist film is formed is placed and heated;
dry ice generation unit for generating dry ice particles with a predetermined particle size; and
an injection nozzle for injecting dry ice particles generated by said dry ice generation unit onto said photo-resist film on said substrate surface at a predetermined injection pressure, wherein
said photo-resist film is removed by blasting dry ice particles with a predetermined particle size onto the photo-resist film at a predetermined injection pressure via said injection nozzle in a state of heating said substrate.

11. The photo-resist film removal device according to claim 10, wherein the heating temperature of said substrate is 30 to 200° C., said predetermined particle size is 10 to 100 μm, and said predetermined injection pressure is 0.2 to 1.0 Mpa.

12. The photo-resist removal device according to claim 10, wherein said photo-resist film is used as a mask in a step of implanting ions into said substrate.

13. A removal film removing device for removing a removal film which is formed on a substrate and of which surface layer is harder than an internal layer, comprising:
a heater stage where a substrate on which said removal film is formed is placed and heated;
dry ice generation unit for generating dry ice particles with a predetermined particle size; and
an injection nozzle for injecting dry ice particles generated by said dry ice generation unit onto said removal film on said substrate surface at a predetermined injection pressure, wherein
the surface layer of said removal film is removed by blasting dry ice particles with a first particle size onto said removal film at a first injection pressure, and the internal layer of said removal film is removed by blasting dry ice particles with a second particle size, which is smaller than said first particle size, onto said removal film, at a second injection pressure, which is lower than said first injection pressure, in a state of heating said substrate.
